(19) United States
(12) Patent Application Publication
(10) Pub. No.: US 2024/0324395 A1
(43) Pub. Date: Sep. 26, 2024

(54) DISPLAY APPARATUS, SUPPORTING MEMBER, METHOD OF MANUFACTURING SUPPORTING MEMBER, AND ELECTRONIC DEVICE

(71) Applicant: BOE Technology Group Co., Ltd., Beijing (CN)

(72) Inventors: Linlin Xu, Beijing (CN); Yonghong Zhou, Beijing (CN); Shangchieh Chu, Beijing (CN); Shiming Shi, Beijing (CN); Meiling Gao, Beijing (CN)

(21) Appl. No.: 18/557,133

(22) PCT Filed: Dec. 16, 2022
(86) PCT No.: PCT/CN2022/139677

§ 371 Date: Oct. 25, 2023

(51) Int. Cl. H10K 59/80; H10K 59/12; H10K 102/00

(52) U.S. Cl. CPC H10K 59/80; H10K 59/1201; H10K 2102/311

(57) ABSTRACT

A display apparatus, a supporting member provided in the display apparatus, a method of manufacturing a supporting member, and an electronic device are provided. The display apparatus includes: a display panel, including a bendable region and a non-bending region; and a supporting member on a back of the display panel. The supporting member includes: a bendable portion configured to support the bendable region, where at least one side of the bendable portion is provided with a first groove; and a supporting portion connected to the bendable portion through the first groove, and configured to support the non-bending region. A density of a material of the bendable portion is different from a density of a material the supporting portion.

### CROSS REFERENCE TO RELATED APPLICATION(S)

This is a Section 371 National Stage Application of International Application No. PCT/CN2022/139677, filed on Dec. 16, 2022, entitled “DISPLAY APPARATUS, SUPPORTING MEMBER, METHOD OF MANUFACTURING SUPPORTING MEMBER AND ELECTRONIC DEVICE”, the content of which is incorporated herein by reference in its entirety.

### TECHNICAL FIELD

The present disclosure relates to a field of display technology, and in particular, to a display apparatus, a supporting member, a method of manufacturing a supporting member, and an electronic device.

### BACKGROUND

A display apparatus is an apparatus that may display information such as texts, images or videos. Examples of the display apparatus include a liquid crystal display apparatus (LCD), an organic light-emitting diode display apparatus (OLED), a plasma display apparatus, etc. In recent years, a flexible display apparatus has attracted more and more attention due to characteristics of bendable, foldable or curlable. In the flexible display apparatus, a flexible display panel may be protected and supported by attaching a supporting structure to a bottom of the flexible display panel. Generally, an entire supporting structure which is made of stainless steel or alloy materials has a large weight, so that a weight of the display apparatus is increased and user experiences are poor.

The above information disclosed in this section is only for the purpose of understanding the background of the invention concept of the present disclosure. Therefore, the above information may include information that does not constitute the related art.

### SUMMARY

In order to solve at least one aspect of the above problems, embodiments of the present disclosure provide a display apparatus, a supporting member, a method of manufacturing a supporting member, and an electronic device.

In an aspect, a display apparatus is provided, including: a display panel, including a bendable region and a non-bending region: a supporting member on a back of the display panel, including: a bendable portion configured to support the bendable region, where at least one side of the bendable portion is provided with a first groove, and a supporting portion connected to the bendable portion through the first groove, and configured to support the non-bending region, where a density of a material of the bendable portion is different from a density of a material of the supporting portion.

According to exemplary embodiments, the bendable portion includes N openings. The N openings are obtained through a first opening process. A time length for processing N openings in the material of the bendable portion using the first opening process is less than a time length for processing N openings in the material of the supporting portion using the first opening process, and where N is greater than or equal to 1.

According to exemplary embodiments, the at least one side of the bendable portion extends in a direction parallel to the display panel. The supporting portion includes a first protrusion. The first protrusion is matched and connected with the first groove.

According to exemplary embodiments, the first groove includes: a right-angle groove facing the display panel. A shape of the first protrusion is matched with the right-angle groove.

According to exemplary embodiments, the bendable portion includes a first plane facing the display panel. The supporting portion includes a second plane facing the display panel. The first plane is coplanar with the second plane.

According to exemplary embodiments, the bendable portion further includes a third plane opposite to the first plane. The supporting portion further includes a fourth plane opposite to the second plane. The third plane is coplanar with the fourth plane.

According to exemplary embodiments, the first protrusion is matched and connected with the first groove through hot pressing or bonding.

According to exemplary embodiments, a bottom of the first groove is provided with M second grooves. Each second groove is filled with a part of the material of the supporting portion. The part of the material of the supporting portion is fixedly connected to the first protrusion. M is greater than or equal to 1.

According to exemplary embodiments, the M second grooves include a wire groove and/or a hole groove; and/or where the M second grooves pass through the bottom of the first groove.

According to exemplary embodiments, each second groove is filled with the part of the material of the supporting portion by hot pressing the part of the material of the supporting portion into each second groove, or each second groove is filled with the part of the material of the supporting portion by embedding M second protrusions on the first protrusion one by one into the M second grooves.

According to exemplary embodiments, the supporting portion includes a third groove on a side away from the display panel. At least part of the bendable portion is embedded in the third groove.

According to exemplary embodiments, the supporting portion includes a fifth plane facing the display panel. The fifth plane is between the bendable portion and the display panel.

According to exemplary embodiments, the at least one side of the bendable portion is provided with S first grooves. Each first groove is filled with a part of the material of the supporting portion. S is greater than or equal to 1.

According to exemplary embodiments, each first groove is filled with the part of the material of the supporting portion by hot pressing the part of the material of the supporting portion into each first groove, or each first groove is filled with the part of the material of the supporting portion by embedding S third protrusions in the third groove one by one into the S first grooves.

According to exemplary embodiments, the first groove includes a riveting hole. The supporting portion is connected to the bendable portion through the first groove by using a riveting process.

According to exemplary embodiments, a bottom of the first groove is provided with at least one riveting hole, and the first protrusion is matched and connected with the first groove through a riveting process.

According to exemplary embodiments, the material of the supporting portion is plastic, the at least one side of the bendable portion includes L fourth protrusions extending in a direction parallel to the display panel. The first groove is formed between any two adjacent fourth protrusions. L is greater than or equal to 2, and where at least part of the plastic is filled into each first groove through an injection molding process.

According to exemplary embodiments, a length of a bottom of the first groove is greater than a length of a notch of the first groove.

According to exemplary embodiments, the material of the bendable portion includes a metal material. The material of the supporting portion includes carbon fiber prepreg or plastic.

According to exemplary embodiments, the material of the supporting portion is carbon fiber prepreg. The supporting portion is formed by laying K layers of carbon fiber prepreg. K is an odd number greater than 1.

According to exemplary embodiments, an elastic modulus of one of any adjacent two layers of carbon fiber prepreg among the K layers of carbon fiber prepreg is different from an elastic modulus of the other one of the any adjacent two layers of carbon fiber prepreg among the K layers of carbon fiber prepreg.

According to exemplary embodiments, the supporting portion includes: a first supporting portion on a first side of the bendable portion, where the first supporting portion is connected to the bendable portion through a first groove on the first side; and a second supporting portion on a second side of the bendable portion, where the second side is opposite to the first side, and the second supporting portion is connected to the bendable portion through a first groove on the second side.

According to exemplary embodiments, the density of the material of the bendable portion is greater than the density of the material of the supporting portion.

According to exemplary embodiments, an elastic modulus of the material of the bendable portion is greater than an elastic modulus of the material density of the supporting portion.

In another aspect, a supporting member is provided in the display apparatus mentioned above. The display apparatus includes a display panel. The supporting member includes: a bendable portion configured to support a bendable region of the display panel, where at least one side of the bendable portion is provided with a first groove; and a supporting portion connected to the bendable portion through the first groove, and configured to support a non-bending region of the display panel, where a density of a material of the bendable portion is different from a density of a material of the supporting portion.

In another aspect, a method of manufacturing a supporting member is provided. The supporting member is provided in the display apparatus mentioned above. The display apparatus includes a display panel. The method includes: forming a bendable portion by using a first material, where the bendable portion includes a first groove on at least one side of the bendable portion and is configured to support the bendable region of the display panel; and forming a supporting portion by using a second material, where the supporting portion is connected to the bendable portion through the first groove and configured to support the non-bending region, where a density of a material of the bendable portion is different from a density of a material of the supporting portion.

According to exemplary embodiments, the supporting portion includes an overlap. The method further includes connecting the supporting portion to the bendable portion through the first groove, where the connecting the supporting portion to the bendable portion through the first groove includes: placing the supporting portion and the bendable portion in a hot pressing mold, where a depth of a region corresponding to the supporting portion in the hot pressing mold is different from a depth of a region corresponding to the bendable portion in the hot pressing mold; and connecting the overlap of the supporting portion to the first groove of the bendable portion by using a hot pressing process.

In another aspect, an electronic device is provided. The electronic device includes the display apparatus mentioned above.

### BRIEF DESCRIPTION OF THE DRAWINGS

Other purposes and advantages of the present disclosure will be apparent from the description of the present disclosure with reference to accompanying drawings in the following text, and may help to have a comprehensive understanding of the present disclosure, in the drawings:

FIG. 1 shows a perspective view of a display apparatus according to exemplary embodiments of the present disclosure;

FIG. 2 shows a plan view of a display apparatus according to exemplary embodiments of the present disclosure:

FIG. 3 shows a cross-sectional view of the display apparatus taken along line AA′ in FIG. 2 according to exemplary embodiments of the present disclosure:

FIG. 4 shows an enlarged plan view of part I of a display apparatus in FIG. 3 according to exemplary embodiments of the present disclosure:

FIG. 5 shows a cross-sectional view of a pixel structure in a display panel of a display apparatus according to exemplary embodiments of the present disclosure:

FIG. 6 shows a cross-sectional view of a display apparatus folded along a bendable region according to exemplary embodiments of the present disclosure:

FIG. 7 shows a cross-sectional view of a display apparatus folded along a bendable region according to other exemplary embodiments of the present disclosure:

FIG. 8 shows a front view of a supporting member according to exemplary embodiments of the present disclosure:

FIG. 9 shows a schematic diagram of a supporting member before connection according to exemplary embodiments of the present disclosure:

FIG. 10 shows a schematic diagram of the supporting member in FIG. 9 after connection according to exemplary embodiments of the present disclosure:

FIG. 11 shows an enlarged plan view of part II of a display apparatus in FIG. 8 according to exemplary embodiments of the present disclosure:

FIG. 12 shows a flowchart of a method of manufacturing a supporting member according to exemplary embodiments of the present disclosure:

FIG. 13 shows a flowchart of a method of manufacturing a supporting member according to other exemplary embodiments of the present disclosure:

FIG. 14 shows a rear view of a supporting member according to exemplary embodiments of the present disclosure:

FIG. 15 shows a cross-sectional view of the supporting member taken along a line BB′ in FIG. 14 according to exemplary embodiments of the present disclosure:

FIG. 16 shows a rear view of the bendable portion in FIG. 14 according to exemplary embodiments of the present disclosure:

FIG. 17(a) to FIG. 17(c) show cross-sectional schematic views of a supporting member according to exemplary embodiments of the present disclosure;

FIG. 18 shows a rear view of a supporting member according to other exemplary embodiments of the present disclosure:

FIG. 19 shows a rear view of a supporting member according to other exemplary embodiments of the present disclosure:

FIG. 20 shows a rear view of the bendable portion in FIG. 19 according to some other exemplary embodiments of the present disclosure;

FIG. 21 shows a schematic diagram of a supporting portion according to exemplary embodiments of the present disclosure:

FIG. 22 shows a schematic diagram of a supporting portion according to other exemplary embodiments of the present disclosure; and

FIG. 23 shows a schematic diagram of a carbon fiber laying layer according to other exemplary embodiments of the present disclosure.

It should be noted that for the sake of clarity, in the accompanying drawings used to illustrate embodiments of the present disclosure, sizes of layers, structures, or regions may be enlarged or reduced, that is, these drawings are not drawn to the actual scale.

### DETAILED DESCRIPTION OF EMBODIMENTS

In the following description, for the purpose of explanation, many specific details are set forth to provide a comprehensive understanding of various exemplary embodiments. However, it is clear that various exemplary embodiments may be implemented without these specific details or with one or more equivalent arrangements. In other cases, well-known structures and devices are shown in block diagram form to avoid unnecessary ambiguity of various exemplary embodiments. In addition, various exemplary embodiments may be different, but need not be exclusive. For example, without departing from the inventive concept, the specific shapes, configurations and characteristics of the exemplary embodiment may be used or implemented in another exemplary embodiment.

In the drawings, for the purpose of clarity and/or description, the size and relative size of the elements may be enlarged. In this way, the size and relative size of each element need not be limited to the size and relative size shown in the drawings. When exemplary embodiments may be implemented differently, a specific process sequence may be executed differently from the described sequence. For example, two consecutive described processes may be substantially performed simultaneously or in a reverse sequence of the described sequence. In addition, the same reference numerals represent the same elements.

When an element is described as being “on”, “connected to”, or “coupled to” another element, the element may be directly on, directly connected to, or directly coupled to the another element, or an intermediate element may exist. However, when an element is described as being “directly on”, “directly connected to”, or “directly coupled to” another element, no intermediate element exist. Other terms and/or expressions used to describe a relationship between elements may be interpreted in a similar manner, e.g., “between” versus “directly between”, “adjacent” versus “directly adjacent”, or “above” versus “directly above” etc. Furthermore, the term “connect” may refer to a physical connection, an electrical connection, a communication connection, and/or a fluid connection. In addition, an X axis, a Y axis and a Z axis are not limited to three axes of a rectangular coordinate system, and may be interpreted in a broader sense. For example, the X, Y, and Z axes may be perpendicular to each other, or may represent different directions that are not perpendicular to each other. For a purpose of the present disclosure, “at least one of X, Y, or Z” and “at least one selected from the group consisting of X, Y, and Z” may be interpreted as X only, Y only, Z only, or any combination of two or more of X, Y and Z, such as XYZ, XYY, YZ and ZZ. As used herein, the term “and/or” includes any and all combinations of one or more of the associated listed items.

It should be understood that, although the terms “first”, “second”, etc., may be used herein to describe various elements, these elements should not be limited by these terms. These terms are only used to distinguish one element from another element. For example, without departing from the scope of exemplary embodiments, a first element may be named as a second element, and similarly, a second element may be named as a first element.

For the purpose of description, spatial relative terms such as “under”, “below”, “beneath”, “lower”, “on”, “above”, “upper”, “higher”, or “side” (such as in “sidewall”) may be used in the present disclosure to describe the relationship between one element and another (or other) element(s) as shown in the drawings. In addition to the orientation depicted in the drawings, the spatial relative terms are also intended to include different orientations of devices during use, operation, and/or manufacturing. For example, if the device in the drawings is turned over, the element or feature described as “below” or “under” the other element may be oriented “above” or “on” the other element or feature. Therefore, the exemplary term “below” may include upper and lower orientations. In addition, the device may be positioned separately (for example, rotated by 90 degrees or in other orientations), and the spatial relative description used in the present disclosure may be explained accordingly.

The terms used herein are for the purpose of describing specific embodiments, and are not intended to be limited. As used herein, unless otherwise explicitly stated in the context, singular forms “a”, and “an” are also intended to include plural forms. Moreover, when the term “including” is used in the specification, the term indicates the existence of stated features, entities, steps, operations, elements, components, and/or their groups, but does not exclude the existence or addition of one or more other features, other entities, other steps, other operations, other elements, other components, and/or their groups. It should also be noted that as used herein, the terms “substantially”, “about” and other similar terms are used as terms for approximation rather than terms for degree. Therefore, the terms “substantially”, “about” and other similar terms are used to illustrate inherent deviations in measured values, calculated values, and/or provided values that those of ordinary skill in the art would recognize.

Unless otherwise limited, all terms (including technical and scientific terms) used herein have the same meaning as commonly understood by those of ordinary skill in the art of which the present disclosure is a part.

Those skilled in the art should understand that, during the elastic deformation stage of a material, a stress and a strain are proportional (i.e. in accordance with Hooke's law), and a proportional coefficient may be referred to as an elastic modulus. “Elastic modulus” is a physical quantity that describes an elasticity of a material, and is a collective term. It can be expressed in terms of “Young's modulus”, “bulk modulus”, etc.

“Bending strength” refers to a maximum stress that a material may withstand when it ruptures or reaches a specified bending moment under bending load. Such stress is a maximum normal stress during bending. It reflects an ability of the material to resist bending and is used to measure the bending performance of the material.

“Opening process” refers to a method and process of using related device to process components to be opened through temperature, chemical reaction, laser or pressure, and ultimately form an opening.

“Hot pressing” refers to placing a component to be connected into a hot pressing mold, fixing the component to be connected to a heating portion with pressure, controlling the temperature and time to achieve hardening and cooling after melting, and then taking out the finished supporting component.

“Riveting process” refers to a method and process of using an axial force to thicken a nail rod pier in a rivet hole of a component and form a nail head, so as to connect components to be connected.

“Injection molding process” refers to a process of manufacturing supporting member with desired shapes by performing operations, such as injection, cooling, detachment on molten raw materials.

“Carbon fiber prepreg” is made by processing carbon fiber bundles, resins, etc. through processes such as coating, hot pressing, cooling, laminating and rolling.

In the following, exemplary embodiments of the present disclosure will be described with reference to the accompanying drawings.

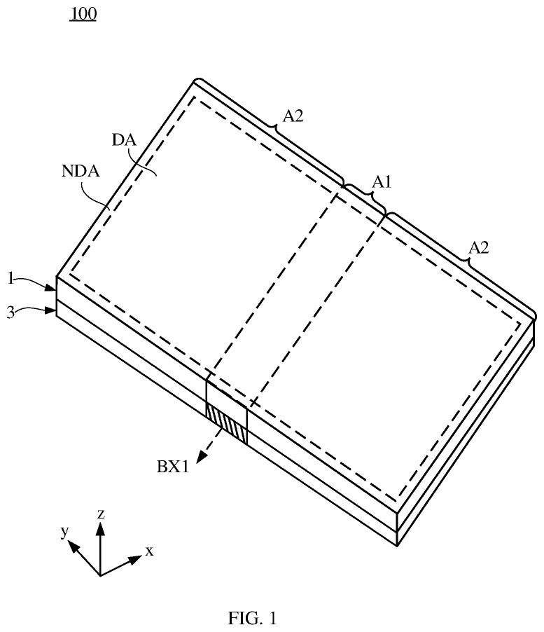

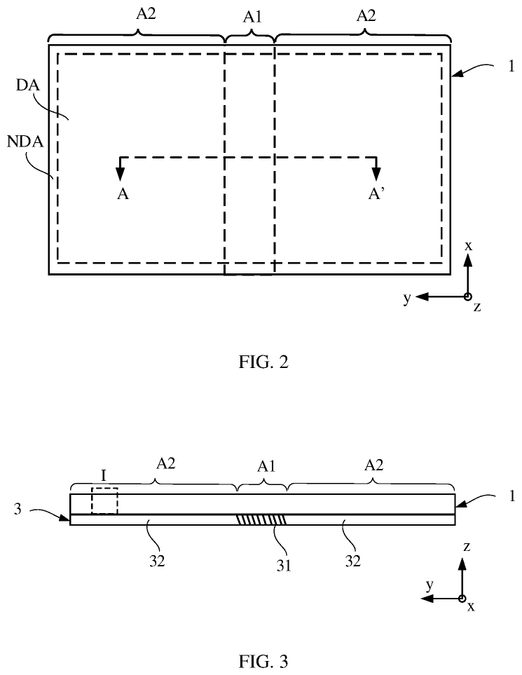

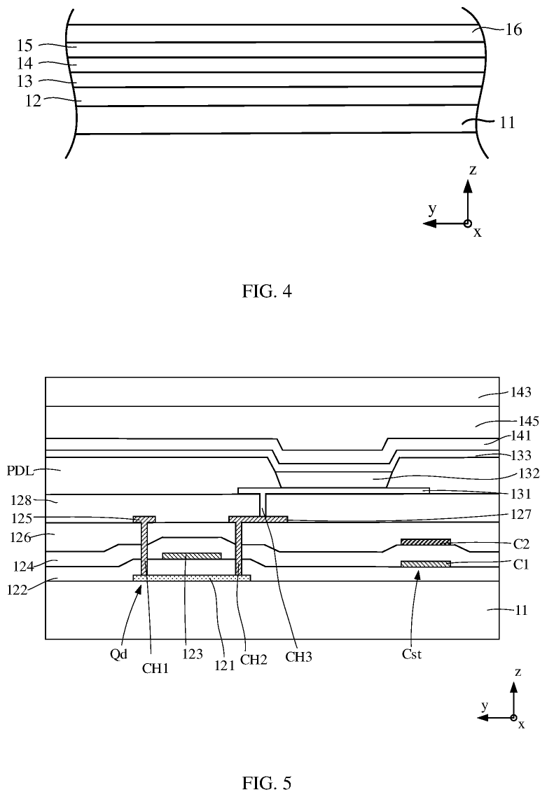

FIG. 1 shows a perspective view of a display apparatus according to exemplary embodiments of the present disclosure. FIG. 2 shows a plan view of a display apparatus according to exemplary embodiments of the present disclosure. FIG. 3 shows a cross-sectional view of the display apparatus taken along line AA′ in FIG. 2 according to exemplary embodiments of the present disclosure. FIG. 4 shows an enlarged plan view of part I of the display apparatus in FIG. 3 according to exemplary embodiments of the present disclosure.

With reference to FIG. 1 and FIG. 2, the display apparatus 100 may be applicable to a mobile terminal, for example. Examples of the mobile terminal include a tablet personal computer (PC), a smartphone, a personal digital assistant (PDA), a portable multimedia player, a game console, or a watch style electronic apparatus. However, embodiments of the present disclosure are not intended to limit types of the mobile terminal that the display apparatus 100 may apply to. In exemplary embodiments, the display apparatus 100 may be used in a large electronic apparatus such as a television (TV) or an external billboard, and may also be used in medium or small electronic apparatuses such as a PC, a laptop, a vehicle navigation apparatus or a camera.

The display apparatus 100 may have a rectangular shape in the plan view. The display apparatus 100 may have two short sides extending in a first direction x and two long sides extending in a second direction y. An angle where the two long sides of the display apparatus 100 intersect with the two short sides of the display apparatus 100 may be a right angle or an arc. Embodiments of the present disclosure are not intended to limit a planar shape of the display apparatus 100. For example, in other embodiments, the display apparatus 100 may have a circular shape, polygonal shape, or other shape in the plan view.

The display apparatus 100 may include a display panel 1 and a supporting member 3.

In exemplary embodiments, the display panel 1 may be a display panel including a light-emitting element. For example, the display panel 1 may include an organic light-emitting diode (OLED), a quantum dot light-emitting diode (QLED), and/or an inorganic material based micro LED (micro-LED). For the convenience of description, taking the display panel 1 including an OLED as an example, elements of the display panel 1 will be described in detail later.

With reference to FIG. 1 to FIG. 4, the display panel 1 of the display apparatus 100 may include elements such as a base substrate 11, a driving layer 12, an organic light-emitting element layer 13, an encapsulation layer 14, a polarizer 15 and a cover plate 16. It should be understood that the display panel 1 may also include other film layers or elements, and embodiments of the present disclosure do not provide an exhaustive description of them.

Unless otherwise specified, the terms “upper”, “top”, “top surface”, and “upward” used herein refer to a display side of the display panel 1, that is, a side of the display panel 1 in a z-axis direction. The terms “lower”, “bottom”, “bottom surface”, “back”, and “downward” used herein refer to a side of the display panel 1 opposite to the display side, that is, a side of the display panel 1 in a reversing direction of the z-axis direction.

The base substrate 11 provides a bottom surface of the display panel 1. The base substrate 11 may be a flexible substrate and may include plastic materials with relatively excellent heat resistance and durability, such as phthalate polyethylene ether, polyethylene naphthalate two formic acid glycol ester (PEN), polycarbonate (PC), polyarylate, polyetherimide, polyethersulfone (PES), or polyimide (PI). For the convenience of description, taking the base substrate 11 including PI as an example.

The display panel 1 includes a bendable region A1 and a non-bending region A2. With reference to FIG. 2, the display panel 1 may be applied to a full screen (for example, a display area DA for displaying information such as images accounts for no less than 90%, which is only an example). The bendable region A1 and the non-bending region A2 shown in FIG. 1 and FIG. 2 may be the display area DA. Embodiments of the present disclosure do not necessarily limit a screen-to-body ratio of the display panel 1. For example, in other embodiments, the display panel 1 may have a display area DA and a non-display area NDA that does not display information such as images. In exemplary embodiments, the non-display area NDA may be adjacent to the display area DA, for example, surrounding the display area DA.

In the plan view, the bendable region A1 may extend through the non-display area NDA in a first direction x. In exemplary embodiments, the bendable region A1 may extend through the non-display area NDA in a second direction y (not shown in the figures).

The display panel 1 may be bent or folded along a bending axis BX1 in the bendable region A1. The bending axis BX1 extends in the bendable region A1 in the first direction x. With the bendable region A1, the display panel 1 may be bent or folded.

It should be noted that in the present disclosure, unless otherwise specified, “bending axis” refers to an imaginary line, rather than to a physical axis or a physical structure. Generally, components having a bending axis may be bent or folded around the bending axis.

In embodiments of the present disclosure, the display panel 1 is a flexible display panel. In addition to a part in the bendable region A1 that may be bent or folded, other parts of the display panel 1 may also be flexible, which may be bent or folded, so as to achieve a flexible display apparatus. The bendable region A1 is a region where the flexible display panel may achieve such as bendable, foldable or curlable functions. A bendable portion 31 of a supporting member 3 is disposed below the bendable region A1. The non-bending region A2 refers to an another region outside the bendable region A1. The flexible display panel in the non-bending region A2 may be also bendable, foldable, or curlable, for example. A supporting portion 32 of the supporting member 3 is disposed below the non-bending region A2.

With reference to FIG. 1 to FIG. 3, the supporting member 3 may be disposed below the display panel 1. In exemplary embodiments, the supporting member 3 may be attached to a bottom surface (back) of the display panel 1. The supporting member 3 may support the flexible display panel 1 and protect the bottom surface of the display panel 1.

The supporting member 3 includes a bendable portion 31 and a supporting portion 32. The bendable portion 31 may overlap (for example, coincide) with the bendable region A1 of the display panel 1, and an orthogonal projection of the bendable region A1 of the display panel 1 on the supporting member 3 falls within the bendable portion 31. The supporting portion 32 may overlap (for example, coincide) with the non-bending region A1 of the display panel 1, and an orthogonal projection of at least part of the non-bending region A2 of the display panel 1 on the supporting member 3 falls within the supporting portion 32.

It is particularly noted that the bendable portion 31 may partially overlap with the bendable region A1 of the display panel 1 instead of completely overlapping. For example, an area of a region of the bendable portion 31 is greater than an area of an orthogonal projection of the bendable region A1 on the supporting member 3, and an orthogonal projection of at least part of the non-bending region A2 on the supporting member 3 falls within the bendable portion.

FIG. 5 shows a cross-sectional view of a pixel structure in a display panel of a display apparatus according to exemplary embodiments of the present disclosure.

For example, FIG. 5 shows a driving transistor Qd in the driving layer 12. The driving transistor Qd includes an active layer 121, a gate electrode 123, a source electrode 125, and a drain electrode 127.

The active layer 121 may be disposed on the base substrate 11. The driving layer 12 may also include a first insulation layer 122 disposed between the active layer 121 and the gate electrode 123. The first insulation layer 122 may insulate the active layer 121 and the gate electrode 123 from each other. The driving layer 12 may also include a gate insulation layer 124 disposed between the gate electrode 123 and the source electrode 125 and between the gate electrode 123 and the drain electrode 127, and a second insulation layer 126 disposed on a side of the gate insulation layer 124 away from the base substrate 11. The source electrode 125 and the drain electrode 127 may be electrically connected to the active layer 121 through contact via holes CH1 and CH2, respectively, and the contact via holes CH1 and CH2 are formed in the first insulation layer 122, the gate insulation layer 124 and the second insulation layer 126.

The driving layer 12 may also include a passivation film 128 disposed on the source electrode 125 and drain electrode 127.

Although it is not specifically shown in FIG. 5, a switching transistor may have a structure that is substantially the same as or similar to the driving transistor Qd, but exemplary embodiments are not limited to this. Alternatively, the switching transistor and the driving transistor Qd may have different structures. For example, an active layer of the switching transistor and an active layer 121 of the driving transistor Qd may be in different layers.

In exemplary embodiments, the driving layer 12 may be disposed in the display area DA, and may also be disposed in the non-display area NDA. For example, the driving layer 12 may also include a plurality of wires electrically connected to a driving integrated circuit (IC). These wires may be located in the non-display area NDA.

It should be understood that the driving layer 12 may also include a capacitor Cst, as shown in FIG. 5. The capacitor Cst includes a first electrode plate C1 and a second electrode plate C2 opposite to and spaced from the first electrode plate C1. For example, the first electrode plate C1 may be located in the same layer as the gate electrode 123. The second electrode plate C2 may be located on a side of the gate insulation layer 124 away from the base substrate 11. For example, the first electrode plate C1 and the second electrode plate C2 may be made of the same material as the gate electrode 123.

The organic light-emitting element layer 13 may include an organic light-emitting element which is served as an emission element. The organic light-emitting element may be of top emission-type and may emit lights in an upward direction, i.e. in the z-axis direction.

With reference to FIG. 5, the organic light-emitting element may include a first electrode 131, an organic layer 132, and a second electrode 133.

The first electrode 131 is disposed on the passivation film 128. The first electrode 131 is electrically connected to the drain electrode 127 through a contact via hole CH3 formed in the passivation film 128. The first electrode 131 may be a pixel electrode or an anode.

The organic layer 132 may include an organic emission layer formed by a small molecule organic material or polymer organic material. The organic emission layer may emit lights based on a voltage difference between the first electrode 131 and the second electrode 133. Although it is not shown, the organic layer 132 may also include at least one of a hole transport layer (HTL), a hole injection layer (HIL), an electron transport layer (ETL) or an electron injection layer (EIL). Therefore, holes from the first electrode 131 and electrons from the second electrode 133 may be injected into the organic layer 132. In the organic emission layer, holes and electrons may be combined to generate excitons. As the excitons transiting from an excited state to a ground state, it is possible to emit lights.

The second electrode 133 may be disposed on the organic layer 132. The second electrode 133 may be a common electrode or a cathode.

The organic light-emitting element layer 13 may also include a pixel defining layer PDL disposed on the passivation film 128.

In exemplary embodiments of the present disclosure, the organic light-emitting element layer 13 may be disposed in the display area DA of the display panel 1, and not in the non-display area NDA.

The encapsulation layer 14 may be disposed on the organic light-emitting element layer 13. The encapsulation layer 14 may protect the organic light-emitting element layer 13 from an influence of external moisture and air.

In exemplary embodiments, the encapsulation layer 14 may be formed as a thin film encapsulation layer and may include at least one organic film and at least one inorganic film. For example, the encapsulation layer 14 may include a first inorganic film 141 disposed on the second electrode 133, an organic film 145 disposed on the first inorganic film 141, and a second inorganic film 143 disposed on the organic film 145. In this way, it is possible to effectively prevent moisture and air from penetrating from an outside of the display panel 1 to an inside of the display panel 1.

With reference to FIG. 3 to FIG. 5, the polarizer 15 is disposed on a side of the encapsulation layer 14 away from the base substrate 11, so as to polarize lights emitted by the organic light-emitting element. It should be understood that the display panel according to the embodiments of the present disclosure may also include other types of optical film layers, which is not limited to the polarizer.

As an example, the polarizer 15 may be disposed in the display area DA of the display panel 1, and not in the non-display area NDA.

The cover plate 16 is attached to the polarizer 15 through an optical adhesive layer. For example, the cover plate 16 may cover an entire upper surface of the display panel 1, that is, covering the display area DA and non-display area NDA of the display panel 1.

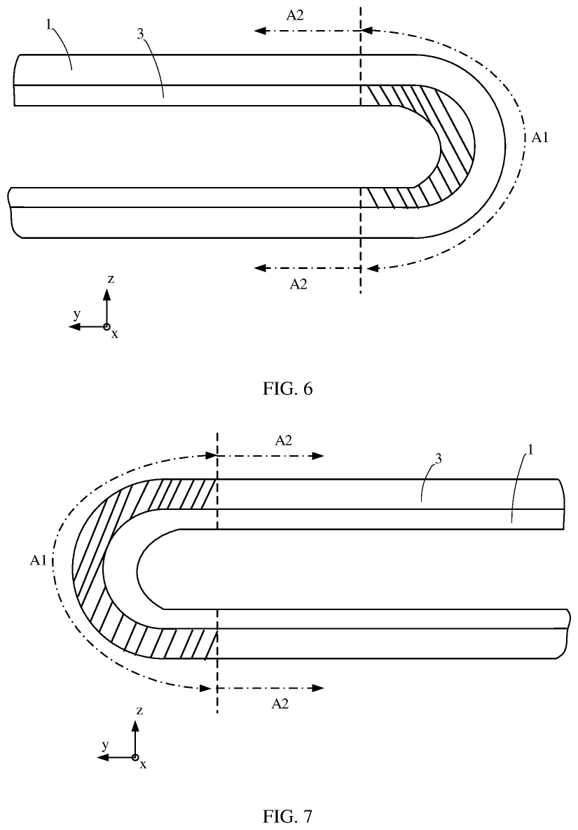

FIG. 6 shows a cross-sectional view of a display apparatus folded along a bendable region according to exemplary embodiments of the present disclosure.

With reference to FIG. 6, the display panel 1 may be folded or bent outward along the bending axis BX1 (shown in FIG. 1) that extends in the first direction x in the bendable region A1. After being folded or bent outward, the display panel 1 may be located externally for users to view. The viewable screen size ultimately obtained may be different, so that it is possible to meet requirements of customers for using products of different sizes, while it is possible to reduce storage sizes of the products, which is convenient for storage and portability. It is also possible to directly turn on the products to see related images on the display panel 1, thereby avoiding frequent folding of the products.

FIG. 7 shows a cross-sectional view of a display apparatus folded along a bendable region according to other exemplary embodiments of the present disclosure.

With reference to FIG. 7, the display panel 1 may be folded or bent inward along the bending axis BX1 (shown in FIG. 1) that extends in the first direction x in the bendable region A1. After being folded or bent inward, the display panel 1 may be located internally. It is possible to reduce storage sizes of the products, which is convenient for storage and portability. It is also possible to protect the display panel 1 in a folded state, and the display panel 1 may be unfolded to achieve a large-size display when viewing is desired.

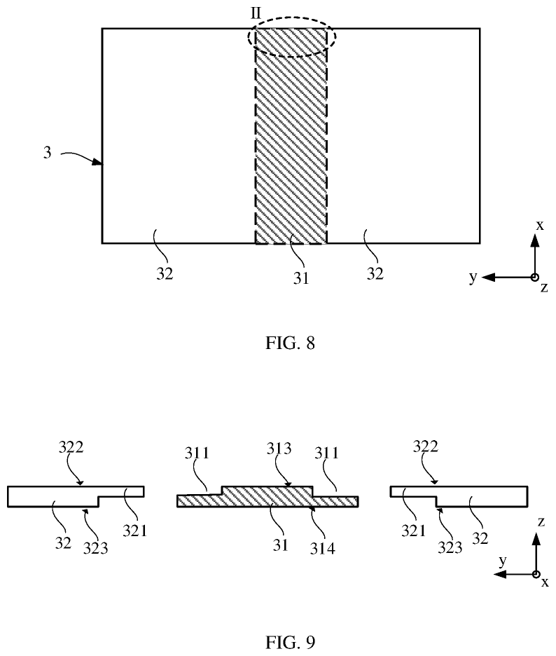

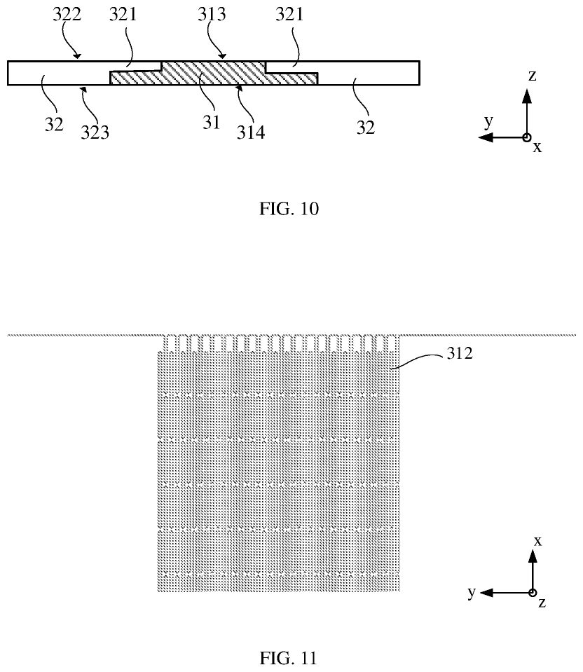

FIG. 8 shows a front view of a supporting member according to exemplary embodiments of the present disclosure. FIG. 9 shows a schematic diagram of a supporting member before connection according to exemplary embodiments of the present disclosure. FIG. 10 shows a schematic diagram of the supporting member in FIG. 9 after connection according to exemplary embodiments of the present disclosure. FIG. 11 shows an enlarged plan view of part II of a display apparatus in FIG. 8 according to exemplary embodiments of the present disclosure.

With reference to FIG. 1 to FIG. 11, the display panel 1 includes a bendable region A1 and a non-bending region A2. The supporting member 3 is on a back of the display panel 1. The supporting member 3 includes a bendable portion 31 and a supporting portion 32. The bendable portion 31 is used to support the bendable region A1. At least one side of the bendable portion 31 is provided with a first groove 311. The supporting portion 32 is connected to the bendable portion 31 through the first groove 311, and used to support the non-bending region A2. A density of a material of the bendable portion 31 is different from a density of a material of the supporting portion 32.

An existing material of the entire supporting member in related art is stainless steel, with a density of about 7.93 g/cm⁻³, which is relatively large. If a large-size supporting member is processed, a weight of the supporting member will be great.

For the supporting member in embodiments of the present disclosure, by setting the density of the material of the bendable portion to be different from that of the supporting portion, the weight problem caused by using the same metal material as a whole in the supporting member may be reduced, and the purpose of weight reduction may be achieved. In addition, connecting the supporting portion to the bendable portion through the first groove may make the connection between the supporting portion and the bendable portion more secure, thereby improving the durability of the supporting member.

For example, a material of the bendable portion 31 may include a metal material, such as stainless steel, titanium alloy, copper alloy, and other metal alloy materials. A material of the supporting portion 32 may include carbon fiber prepreg or plastic, etc.

In some embodiments, the bendable portion 31 includes N openings 312. The N openings 312 are obtained through a first opening process. A time length for processing N openings 312 in the material of the bendable portion 31 using the first opening process is less than a time length for processing N openings 312 in the material of the supporting portion 32 using the first opening process. N is greater than or equal to 1.

For example, with reference to FIG. 11, each opening 312 passes through the bendable portion 31, and has a shape of slender oval. Each adjacent two columns of openings 312 are disposed in a staggered manner, and two columns of openings 312 spaced by one column of openings are disposed in an aligned manner. Embodiments of the present disclosure are not intended to limit N openings 312 in a schematic scheme shown in FIG. 11. For example, shapes of the openings 312, an arrangement of the openings 312, or depths of the openings 312 may be flexibly disposed. For example, the opening 312 may be in a shape of diamond, rectangle, circle or polygon. The arrangement of the openings 312 may be achieved according to a specific pattern.

As described above, using stainless steel for the entire supporting member 3 in the related art results in a larger weight of the display apparatus. However, the material, such as carbon fiber or plastic, has a small density, which may greatly reduce weight when used in the design of the supporting member 3. However, for example, the pattern processing of carbon fiber material may only use a laser opening process, which is very inefficient. Especially when the supporting member 3 is used for a large-size display panel 1, it is not suitable for mass manufacturing. For example, the laser opening process may only drill holes one by one, which has a low efficiency. An 8-inch product needs 20 to 30 minutes. If the supporting member 3 is adapted to a larger-size folded display panel 1, it will take more than an hour and does not have a capability for mass manufacturing.

For example, a first opening process includes an etching process. For example, the material of the bendable portion 31 includes a metal material, and the material of the supporting portion 32 includes carbon fiber prepreg or plastic. The etching process may be used to quickly obtain N openings 312 in the bendable portion 31, but it may not be possible to obtain openings 312 when the etching process is used on carbon fiber prepreg. In this case, it also belongs to that a time length for processing N openings 312 in the material of the bendable portion 31 using the first opening process is less than a time length for processing N openings 312 in the material of the supporting portion 32.

In an aspect, N openings 312 are disposed in the bendable portion 31, and it is possible to further reduce the weight of the supporting member 3 and reduce an equivalent modulus of the bendable portion 31, so as to facilitate bending. In another aspect, by combining materials of different densities and using a material with fast processing speed for the openings 312 as a material of the bendable portion 31, it is possible to improve the efficiency of processing.

It should be noted that, the first opening process may also include other opening processes. Under a premise of achieving weight reduction and improving the efficiency of processing, it is not limited to the above etching process, nor is it limited to the material of the bendable portion 31 being metal, and the material of the supporting portion 32 being carbon fiber prepreg or plastic.

In embodiments, at least one side of the bendable portion 31 extends in a direction parallel to the display panel 1. The supporting portion 32 includes a first protrusion 321. The first protrusion 321 is matched and connected with the first groove 311.

With reference to FIG. 9 and FIG. 10, an xy plane is parallel to the display panel 1, and the first direction x and the second direction y are parallel to the display panel 1. In this embodiment, at least one side of the bendable portion 31 may include one side or two sides extending in the second direction y.

It should be noted that although FIG. 9 and FIG. 10 show that the bendable portion 31 has two opposite first grooves 311, the first groove 311 may also be disposed on one side in the second direction y. For example, the first groove 311 is disposed on a left side as shown in FIG. 9, while the right side of the bendable portion 31 is integrally formed with the supporting portion 3232 and the materials thereof are the same, for example, both of which are metal materials.

In embodiments, the first groove 311 includes a right-angle groove facing the display panel 1, and a shape of the first protrusion 321 is matched with the right-angle groove.

With reference to FIG. 9 and FIG. 10, taking the first groove 311 on a right side as an example, the first groove 311 is in a shape of “L”. A shape of the first protrusion 321 is cuboid, and a groove in a shape of the first groove 311 rotated clockwise 180 degrees is below the first protrusion 321, the component after connection is shown in FIG. 10. In embodiments, the first grooves 311 on the left and right sides may be the same, for example, parameters such as shapes, depths and widths are the same. In other embodiments, the first groove 311 on the left side may be different from the first groove 311 on the right side, for example, at least one parameter such as shape, depth and width is different. The shape of the first protrusion 321 is accordingly adjusted according to the first groove 311 matched and connected with the first protrusion 321.

In other embodiments, the first groove 311 may also be disposed away from the display panel 1. For example, the first groove shown in FIG. 10 is rotated 180 degrees downwards around the y-axis, so that a lower end surface of the current bendable portion 31 faces the display panel 1 after rotating, thereby increasing a contact area with the display panel 1 and reducing an impression.

In other embodiments, the first groove 311 may adopt other forms than the right-angle groove. For example, as shown in FIG. 9, a bottom of the first groove 311 is convex, a bottom of the corresponding first protrusion 321 is concave, and the two may be engaged with each other, so as to resist forces in the x or y direction.

In embodiments, with reference to FIG. 10, the bendable portion 31 includes a first plane 313 facing the display panel 1. The supporting portion 32 includes a second plane 322 facing the display panel 1. The first plane 313 is coplanar with the second plane 322.

For example, after the first protrusion 321 is connected to the first groove 311, the first plane 313 and the second plane 322 are in the same plane. Being coplanar refers to a flatness being within an allowable range, such as less than or equal to 2 mm. In this way, the supporting member 3 may be better fitted with the display panel 1 and have a better performance for supporting.

With reference to FIG. 10, the first plane 313 and the second plane 322 are in the same plane, a thickness of the bendable portion 31 may be less than or equal to a thickness of the supporting member 3.

In embodiments, with reference to FIG. 9 and FIG. 10, the bendable portion 31 further includes a third plane 314 opposite to the first plane 313. The supporting portion 32 further includes a fourth plane 323 opposite to the second plane 322. The third plane 314 is coplanar with the fourth plane 323.

For example, after the first protrusion 321 is connected to the first groove 311, the third plane 314 and the fourth plane 323 are in the same plane. Being coplanar refers to a flatness being within an allowable range, such as less than or equal to 2 mm. In this way, a thickness of the entire supporting member 3 is consistent, that is, a thickness of the bendable portion 31 is equal to a thickness of the supporting member 3, so as to avoid a problem that a middle of the supporting member 3 is concave and unable to provide support when a thickness of the middle of the supporting member 3 is less than that of two sides, thereby resulting in a deeper impression.

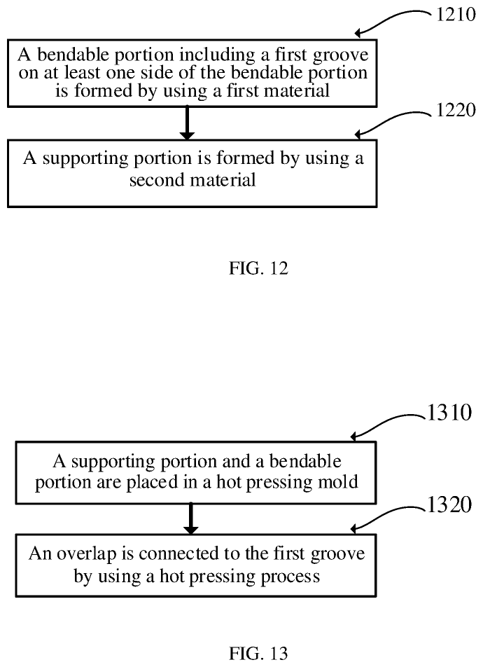

In embodiments, the first protrusion 321 is matched and connected with the first groove 311 through hot pressing or bonding. The process of manufacturing the supporting member 3 is further described with reference to FIG. 12 and FIG. 13.

FIG. 12 shows a flowchart of a method of manufacturing a supporting member 3 according to exemplary embodiments of the present disclosure. FIG. 13 shows a flowchart of a method of manufacturing a supporting member 3 according to other exemplary embodiments of the present disclosure.

In operation S1210, a bendable portion 31 including a first groove 311 on at least one side of the bendable portion is formed by using a first material. The bendable portion 31 is used to support the bendable region A1 of the display panel 1.

For example, the bendable portion 31 may be made of a metal part, such as titanium alloy and stainless steel, N openings 312 may be processed to form a hollow pattern region. The hollow pattern region may be processed by an etching method which may use a mask to perform a chemical etching.

In operation S1220, a supporting portion 32 is formed by using a second material. The supporting portion is connected to the bendable portion 31 through the first groove 311 and used to support the non-bending region A2. A density of a material of the bendable portion 31 is different from a density of a material of the supporting portion 32.

For example, the supporting portion 32 may be made of carbon fiber prepreg or plastic.

An example is given by combining operation S1210 and operation S1220, the metal part is processed, while an etching of a middle pattern region is completed by the etching method. Then, a hot pressing mold is made. Due to the use of two materials, metal and carbon fiber prepreg have different thermal expansion rates under high temperature and high pressure, and it is not possible to create flat steel sheets on both sides using the mold that processes the same material. According to the actual composite scheme drawing, it is required to make a concave-convex design corresponding to positions of different materials, so as to match with thermal expansion rates of different materials and achieve a flat effect of the surface after hot pressing, so that a flatness of a composited plate may be less than or equal to 2 mm. Next, the carbon fiber prepreg is cut according to the size of the supporting member 3. Next, the mold is cleaned. It is required to clean impurities and dusts inside the mold to ensure that the surface of the mold is clean and tidy, so as to prevent foreign matter from being on the surface of the supporting member 3. Then, a release agent is applied. After the mold is cleaned, a releasing agent is applied on it. After the supporting member 3 is formed, a releasing of the supporting member 3 is completed, so as to avoid the bonding between the supporting member 3 and the mold. Then, the carbon fiber prepreg is laid to form a prototype of the supporting portion 32.

Next, operations S1310 and S1320 are performed as follows.

In operation S1310, a supporting portion 32 and a bendable portion 31 are placed in a hot pressing mold. A depth of a region corresponding to the supporting portion 32 in the hot pressing mold is different from a depth of a region corresponding to the bendable portion 31 in the hot pressing mold. The supporting portion 32 includes an overlap.

The overlap is the first protrusion 321 shown in FIG. 9 and FIG. 10. The depth is in the direction of the z-axis. The mold portions corresponding to the bottom and top of the supporting member 3 may be designed in a concave-convex manner.

Specifically, a mold is filled, such as placing the metal part in the middle of the mold, and then the carbon fiber prepreg is filled according to a laying sequence so as to ensure a flatness of the laying layer. Next, the mold is assembled, that is, the mold is fixed by screws, so as to ensure the size of the molded product.

In operation S1320, an overlap is connected to the first groove 311 by using a hot pressing process.

Specifically, a curing molding is performed. The mold is sent onto a hot pressing machine for pressure and temperature control. After a period of time, the mold is cooled. Then, the releasing is performed, the mold is removed, and the supporting member 3 is taken out.

As described above, after the metal part is processed, the etching of the middle pattern region is synchronously completed by using the etching method. In other embodiments, the shape of the metal part is etched, but the middle pattern is not etched. Then, the metal part is combined with the carbon fiber prepreg, and an entire shape is obtained by hot pressing (the hot pressing mold is also designed in a concave-convex manner). The size obtained after hot pressing may be greater than the size of the resultant product, which is for the precise cutting of the subsequent product size. Then, the carbon fiber portion of the product is wrapped, and the metal part is etched to obtain a middle pattern. Then, an oversized part of the carbon fiber prepreg is cut by performing a laser cutting, so as to obtain the size of the resultant product. The advantage of performing pattern etching after hot pressing in this embodiment is that the pattern may be maintained a good size and shape, thereby avoiding deformation and resin flowing into the openings during hot pressing.

In embodiments, in order to increase bonding force, a layer of adhesive may be applied between the overlap and the first groove 311 before the mold is hot pressed, and the surface of the first groove 311 is roughened, so as to increase the bonding force. For example, the surface of the first groove 311 is polished and placed in the mold, the adhesive is applied to the polished region, then the carbon fiber prepreg is laid, and then the hot pressing is performed on the mold to obtain the molded supporting member 3.

In other embodiments, the bonding manner may be used separately. For example, after operations S1210 and S1220 are performed to obtain the bendable portion 31 and the supporting portion 32, the adhesive may be applied to a joint between the overlap and the first groove 311 for bonding.

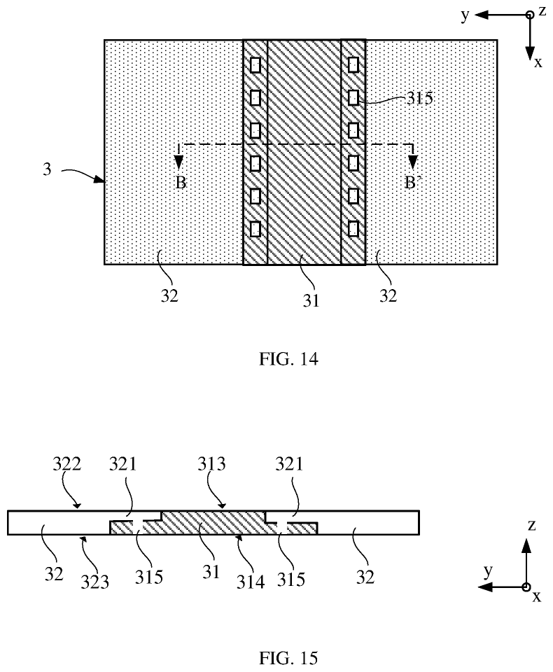

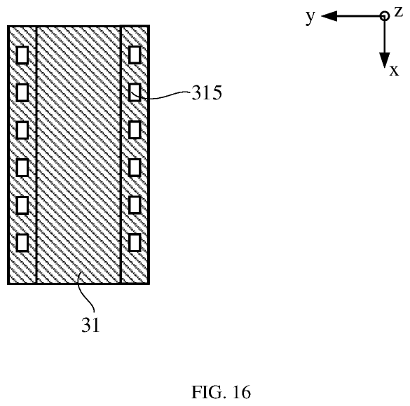

FIG. 14 shows a rear view of a supporting member 3 according to exemplary embodiments of the present disclosure. FIG. 15 shows a cross-sectional view of the supporting member 3 taken along a line BB′ in FIG. 14 according to exemplary embodiments of the present disclosure. FIG. 16 shows a rear view of the bendable portion 31 in FIG. 14 according to exemplary embodiments of the present disclosure. In order to clearly illustrate structures of the embodiments, the supporting portion 32 in FIG. 14 is filled with a dotted pattern.

In embodiments, with reference to FIG. 14 to FIG. 16, a bottom of the first groove 311 is provided with M second grooves 315. Each second groove 315 is filled with a part of the material of the supporting portion 32. The part of the material of the supporting portion 32 is fixedly connected to the first protrusion 321. M is greater than or equal to 1.

According to embodiments of the present disclosure, each second groove 315 is filled with the part of the material of the supporting portion 32, which increases the bonding force between the bendable portion 31 and the supporting portion 32. As part of the material of the supporting portion 32 extends into or even passes through the second groove 315 of the bendable portion 31, it may at least resist the force in the x or y direction, so that the bendable portion 31 and the supporting portion 32 are not easily separated during multiple bending processes.

In embodiments, the M second grooves 315 include a wire groove and/or a hole groove; and/or the M second grooves 315 pass through the bottom of the first groove 311.

For example, the hole groove may include a concave portion in a shape of circle, rectangle or other polygon. The wire groove includes a concave portion in a shape of interval or rectangle. The wire groove may be formed by a plurality of connected holes. The second groove 315 may be a through groove or a blind groove. The through groove passes through the bottom of the first groove 311. A depth of the blind groove is less than a thickness of the bottom of the first groove 311, that is, the blind groove does not pass through the bottom of the first groove 311.

In embodiments, each second groove 315 is filled with the part of the material of the supporting portion 32 by hot pressing the part of the material of the supporting portion 32 into each second groove 315.

For example, with reference to FIG. 14 to FIG. 16, and operation S1210 and operation S1220, operation S1310 and operation S1320, when manufacturing the supporting member 3, after the metal part is placed in the mold, when laying the carbon fiber prepreg, in addition to large pieces of carbon fiber prepreg on two sides, a region of the second groove 315 (such as above and/or inside the second groove 315) is also laid with small pieces of carbon fiber prepreg. In a process of the hot pressing, the resin in the region of the second groove 315 is melted and filled into the second groove 315, and the first protrusion 321 is connected to other parts of the first groove 311 due to the hot pressing. In addition, the aforementioned small pieces of carbon fiber prepreg are laid below a region of the first protrusion 321 before hot pressing, and are fixedly connected to the first protrusion 321 after hot pressing.

In other embodiments, each second groove 315 is filled with the part of the material of the supporting portion 32 by embedding M second protrusions on the first protrusion 321 one by one into the M second grooves 315.

For example, M second protrusions are fixedly connected below the first protrusion 321. After applying adhesive, each second protrusion is embedded into a corresponding second groove 315. Alternatively, after each second protrusion is embedded into the corresponding second groove 315, a hot pressing molding is performed.

With reference to FIG. 15, a thickness of the bendable portion 31 in this embodiment may be less than or equal to a thickness of the supporting member 3.

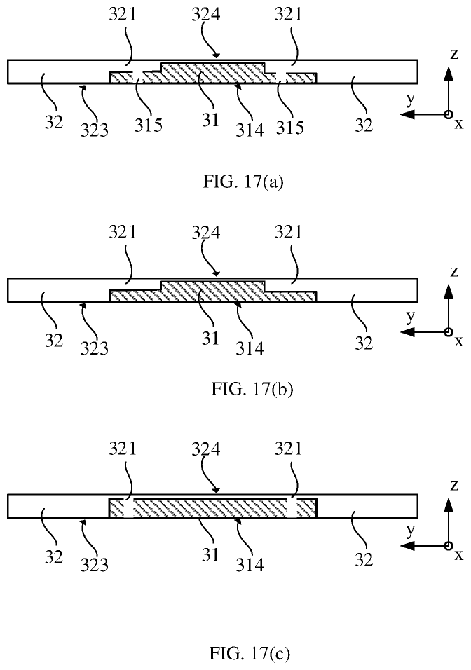

FIG. 17(a) to FIG. 17(c) show cross-sectional schematic views of a supporting member 3 according to exemplary embodiments of the present disclosure.

In embodiments, the supporting portion 32 includes a third groove on a side away from the display panel 1. At least part of the bendable portion 31 is embedded into the third groove. With reference to FIG. 17(a) to FIG. 17(c), the third groove is a concave portion filled with the bendable portion 31 below the supporting portion 32.

In embodiments, the supporting portion 32 includes a fifth plane 324 facing the display panel 1. The fifth plane 324 is between the bendable portion 31 and the display panel 1. With reference to FIG. 17(a) to FIG. 17(c), a surface layer of the supporting member 3 facing the display panel 1 is made of carbon fiber prepreg, and the bendable portion 31 is embedded into a lower part of the supporting member 3. This method may increase a flatness of the surface and reduce the impression.

In embodiments, at least one side of the bendable portion 31 is provided with S first grooves 311. Each first groove 311 is filled with a part of the material of the supporting portion 32. S is greater than or equal to 1.

In embodiments, each first groove 311 is filled with the part of the material of the supporting portion 32 by hot pressing the part of the material of the supporting portion 32 into each first groove 311. Alternatively, each first groove 311 is filled with the part of the material of the supporting portion 32 by embedding S third protrusions in the third groove one by one into the S first grooves 311.

With reference to FIG. 17(a), the first groove 311 may be a right-angle groove. The right-angle groove may pass through the first direction x. A single side is provided with only one right-angle groove. Alternatively, the number of the right-angle grooves may be multiple, which are spaced from each other and arranged in the first direction x. In addition, a bottom of the right-angle groove may include one or more second grooves 315. Each first groove 311 and each second groove 315 are filled with part of the material of the supporting portion 32. Filling in this embodiment may be achieved by embedding pre-molded protrusions on the supporting portion 32, or by melting the resin after the laid carbon fiber prepreg is hot pressed.

With reference to FIG. 17(b), except for the absence of the second groove 315, the rest are consistent with FIG. 17(a), which will not be repeated here.

With reference to FIG. 17(c), the first groove 311 in this embodiment is a concave portion formed in a third direction z. The first groove 311 may be a through groove or a blind groove. An upper surface of the bendable portion 31 is connected to the third groove. The first groove 311 is filled with part of the material of the supporting portion 32, such as being embedded by S third protrusions, or filled by melting the resin after the carbon fiber prepreg is hot pressed. It is possible to resist forces in directions of x, y, or z.

For example, with reference to FIG. 17(a) to FIG. 17(c), in a manufacturing process, the bendable portion 31 may be placed in the mold, and the carbon fiber prepreg may be laid layer by layer. This embodiment involves laying one or more layers of carbon fiber prepreg on the top of the bendable portion 31 to form a fifth plane 324. A position of the fifth plane 324 is the same as that of the second plane 322. With reference to the embodiments of FIG. 10 or FIG. 15, the second plane 322 includes two separated parts, while the fifth plane 324 is a whole.

With reference to FIG. 17(a) to FIG. 17(c), the third plane 314 of the bendable portion 31 in this embodiment may be coplanar with the fourth plane 323 of the supporting portion 32, or may be inward concave relative to the fourth plane 323.

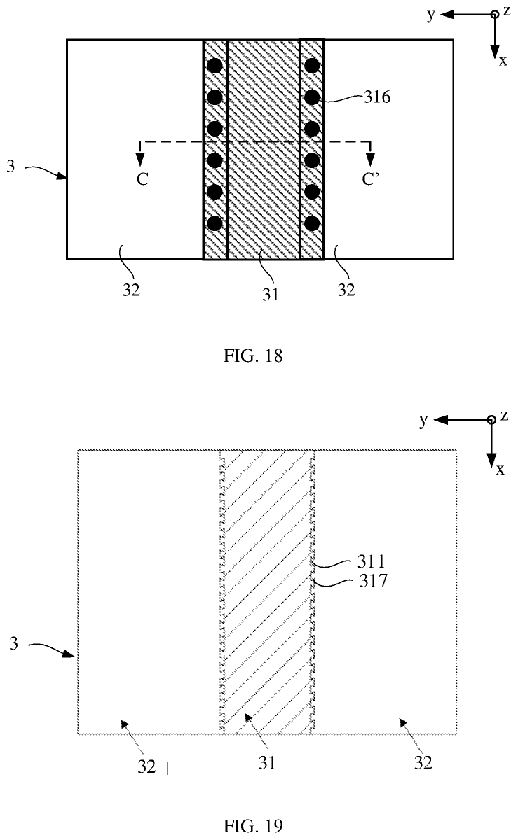

FIG. 18 shows a rear view of a supporting member 3 according to other exemplary embodiments of the present disclosure. The cross-sectional view taken along line CC′ in FIG. 18 may refer to FIG. 15, FIG. 17(a) or FIG. 17(c).

In embodiments, the bendable portion 31 is shown as FIG. 17(c), and the first groove 311 includes a riveting hole 316. The supporting portion 32 is connected to the bendable portion 31 through the first groove 311 by using a riveting process.

In embodiments, the bendable portion 31 is shown as FIG. 15 and FIG. 17(a), a bottom of the first groove 311 is provided with at least one riveting hole 316, and the first protrusion 321 is matched and connected with the first groove 311 through a riveting process.

According to embodiments of the present disclosure, when an external force is applied in the x or y direction to separate the supporting portion 32 and the bendable portion 31, it is possible to effectively block by rivets.

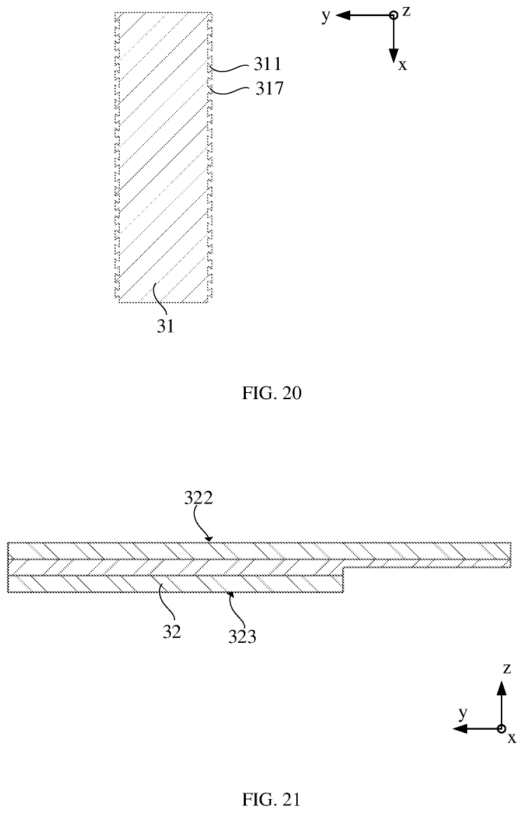

FIG. 19 shows a rear view of a supporting member 3 according to other exemplary embodiments of the present disclosure. FIG. 20 shows a rear view of the bendable portion 31 in FIG. 19 according to other exemplary embodiments of the present disclosure.

In embodiments, the material of the supporting portion 32 is plastic, the at least one side of the bendable portion includes L fourth protrusions 317 extending in a direction parallel to the display panel 1. The first groove 311 is formed between any two adjacent fourth protrusions 317. L is greater than or equal to 2. At least part of the plastic is filled into each first groove 311 through an injection molding process.

For example, the bendable portion 31 is a metal part, the method of injection molding process is to process the metal part, pre-fix it in a proper position in the mold, and then inject plastic for molding. After the mold is opened, the metal part is tightly wrapped and embedded into the product by the cooled and solidified plastic. Plastic material may be selected from materials such as nylon glass fiber, PC glass fiber, PBT, etc.

In embodiments, a length of a bottom of the first groove 311 perpendicular to an extending direction of the fourth protrusion is greater than that of a notch of the first groove 311. For example, the fourth protrusion 317 is in a shape of a regular trapezoid as shown in FIG. 19 and FIG. 20, the first groove 311 is in a shape of an inverted trapezoid. For example, the fourth protrusion 317 is in a shape of “T”, and a horizontal line in the “T” faces outward, the first groove 311 is in a shape of a rectangle with a gap (i.e. a notch) formed by two adjacent “T”. The design that a length of the bottom of the groove is greater that of the notch of the groove increases a bonding force between two materials.

With reference to FIG. 19 and FIG. 20, the first plane 313 of the bendable portion 31 may be coplanar with the second plane 322 of the supporting portion 32 (as shown in FIG. 10 and FIG. 15), and the fifth plane 324 of the supporting portion 32 may be above the bendable portion 31 (as shown in FIG. 17(a) to FIG. 17(c)). The third plane 314 of the bendable portion 31 of this embodiment may be coplanar with the fourth plane 323 of the supporting portion 32, or may be inward concave relative to the fourth plane 323.

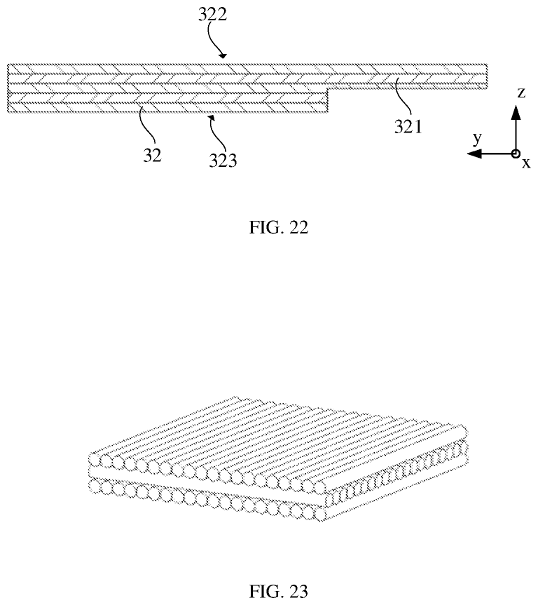

FIG. 21 shows a schematic diagram of a supporting portion according to exemplary embodiments of the present disclosure. FIG. 22 shows a schematic diagram of a supporting portion according to other exemplary embodiments of the present disclosure. FIG. 23 shows a schematic diagram of a carbon fiber laying layer according to other exemplary embodiments of the present disclosure.

In embodiments, the material of the supporting portion 32 is carbon fiber prepreg, the supporting portion 32 is formed by laying K layers of carbon fiber prepreg, and K is an odd number greater than 1.

FIG. 21 shows a schematic diagram of a supporting portion 32 obtained from three layers of carbon fiber prepreg, in which the first protrusion 321 has a thickness of 1.5 layers of carbon fiber prepreg. FIG. 22 shows a schematic diagram of a supporting portion 32 obtained from five layers of carbon fiber prepreg, in which the first protrusion 321 has a thickness of 2.5 layers of carbon fiber prepreg. Specifically, the thickness of the first protrusion 321 is only an example and may be flexibly disposed.

For example, a structure of the supporting portion in this embodiment is that fiber directions of adjacent layers are perpendicular to each other, and an entire principle of symmetry is followed, so that the total number of layers is an odd number. As shown in FIG. 23, angles between the fiber directions of respective layers are staggered, and the layers are laid sequentially according to 0°/90°. As the carbon fiber is an anisotropic material which having mechanical properties in the fiber direction, the layers of carbon fiber prepreg are laid in different directions, so as to increase mechanical properties in other directions. In other embodiments, the layers may also be sequentially laid according to +45°/−45°.

In embodiments, elastic moduli of any adjacent two layers of carbon fiber prepreg may be the same, that is, carbon fiber filaments are of the same type. For example, as shown in FIG. 21, when the three layers are laid with T700 carbon fiber filaments, a whole elastic modulus is about 50 Gpa to 60 Gpa.

In other embodiments, an elastic modulus of one of any adjacent two layers of carbon fiber prepreg among the K layers of carbon fiber prepreg is different from an elastic modulus of the other one of the any adjacent two layers of carbon fiber prepreg among the K layers of carbon fiber prepreg. For example, as shown in FIG. 21, when the three layers are laid with T700/M40/T700 carbon fiber filaments, respectively, the whole modulus is about 70 Gpa to 150 Gpa, so as to increase a bendability and stiffness of the supporting element 3.

In embodiments, with reference to FIG. 1 to FIG. 16 and FIG. 18 to FIG. 23, the supporting portion 32 includes: a first supporting portion 32 on a first side of the bendable portion 31; and a second supporting portion 32 on a second side of the bendable portion 31. The first supporting portion 32 is connected to the bendable portion 31 through a first groove 311 on the first side, and the second supporting portion 32 is connected to the bendable portion 31 through a first groove 311 on the second side, the second side is opposite to the first side.

In embodiments, with reference to FIG. 1 to FIG. 23, the density of the material of the bendable portion 31 is greater than the density of the material of the supporting portion 32. As described above, the material of the bendable portion 31 adopts a metal material, and the material of the supporting portion 32 adopts carbon fiber prepreg or plastic.

In embodiments, with reference to FIG. 1 to FIG. 23, an elastic modulus of the material of the bendable portion 31 is greater than an elastic modulus of the material of the supporting portion 32. For example, the material of the bendable portion 31 adopts metal material, and the material of the supporting portion 32 adopts carbon fiber prepreg, the elastic modulus of the metal material is greater than the elastic modulus of the carbon fiber prepreg. For example, the elastic modulus of stainless steel is about 200 GPa, and the above three layers are laid with T700/M40/T700 carbon fiber filaments, respectively, the whole modulus is about 70 Gpa to 150 Gpa. Therefore, the elastic modulus of stainless steel is greater than the elastic modulus of the supporting portion or the elastic modulus of a single layer of carbon fiber prepreg.

In other embodiments of the present disclosure, an electronic device is also provided. The electronic device may be a device including display functions, that is, a device that includes the aforementioned display apparatus. For example, the electronic device may be a smartphone, a mobile phone, a video phone, an e-book reader, a desktop computer (PC), a laptop, a netbooks PC, a personal digital assistants (PDA), a portable multimedia players (PMP), a digital audio player, a mobile medical device, a cameras, a wearable device (such as a head-mounted device, an electronic clothing, an electronic bracelet, an electronic necklace, an electronic accessories, an electronic tattoo, or a smart watch).

The electronic device according to embodiments of the present disclosure may be smart home appliances that include a display function. For example, smart home appliances may be televisions, digital video disc (DVD) players, sound systems, refrigerators, air conditioners, vacuum cleaners, ovens, microwaves, washing machines, dryers, air purifiers, set-top boxes, television (TV) boxes, game consoles, electronic dictionaries, electronic keys, camera recorders, electronic photo frames, etc.

According to the embodiments of the present disclosure, electronic devices may be medical devices (such as magnetic resonance angiography (MRA) devices, magnetic resonance imaging (MRI) devices, computed tomography (CT) devices, imaging devices, or ultrasound devices), navigation devices, global positioning system (GPS) receivers, event data recorders (EDRs), flight data recorders (FDRs), automotive information and entertainment devices, marine electronic devices (such as marine navigation devices, gyroscopes or compasses), avionics, security devices, industrial or consumer robots, automatic teller machines (ATMs), point of sale (POS), etc.

According to embodiments of the present disclosure, electronic devices may include furniture with display functions, parts of buildings/structures, electronic bulletin boards, electronic signature receiving devices, projectors, various measurement devices (such as water meters, electricity meters, gas meters, or electromagnetic wave measurement devices), etc. According to some embodiments, electronic devices may be any combination of the aforementioned devices. In addition, electronic devices according to various embodiments may be flexible devices. In addition, those skilled in the art should be aware that electronic devices according to various embodiments of the present disclosure are not limited to the aforementioned devices.

Although some embodiments according to an entire inventive concept of the present disclosure have been illustrated and explained, those of ordinary skill in the art will understand that changes may be made to these embodiments without departing from the principles and spirit of the entire inventive concept of the present disclosure and the scope of the present disclosure is limited by the claims and their equivalents.

1. A display apparatus, comprising:
a display panel, comprising a bendable region and a non-bending region; and
a supporting member on a back of the display panel, comprising:
a bendable portion configured to support the bendable region, wherein at least one side of the bendable portion is provided with a first groove, and
a supporting portion connected to the bendable portion through the first groove, and configured to support the non-bending region, wherein a density of a material of the bendable portion is different from a density of a material of the supporting portion.

2. The display apparatus of claim 1, wherein the bendable portion comprises N openings, the N openings are obtained through a first opening process, a time length for processing N openings in the material of the bendable portion using the first opening process is less than a time length for processing N openings in the material of the supporting portion using the first opening process, and wherein N is greater than or equal to 1.

3. The display apparatus of claim 1, wherein the at least one side of the bendable portion extends in a direction parallel to the display panel, and
wherein the supporting portion comprises a first protrusion, and the first protrusion is matched and connected with the first groove.

4. The display apparatus of claim 3, wherein the first groove comprises:
a right-angle groove facing the display panel, and a shape of the first protrusion is matched with the right-angle groove.

5. The display apparatus of claim 4, wherein the bendable portion comprises a first plane facing the display panel, the supporting portion comprises a second plane facing the display panel, and the first plane is coplanar with the second plane.

6. The display apparatus of claim 5, wherein the bendable portion further comprises a third plane opposite to the first plane, the supporting portion further comprises a fourth plane opposite to the second plane, and the third plane is coplanar with the fourth plane.

7. The display apparatus of claim 3, wherein the first protrusion is matched and connected with the first groove through hot pressing or bonding.

8. The display apparatus of claim 3, wherein a bottom of the first groove is provided with M second grooves, each second groove is filled with a part of the material of the supporting portion, the part of the material of the supporting portion is fixedly connected to the first protrusion, and wherein M is greater than or equal to 1.

9. The display apparatus of claim 8, wherein the M second grooves comprise a wire groove and/or a hole groove; and/or
wherein the M second grooves pass through the bottom of the first groove.

10. The display apparatus of claim 8, wherein each second groove is filled with the part of the material of the supporting portion by hot pressing the part of the material of the supporting portion into each second groove; or
wherein each second groove is filled with the part of the material of the supporting portion by embedding M second protrusions on the first protrusion one by one into the M second grooves.

11. The display apparatus of claim 1, wherein the supporting portion comprises a third groove on a side away from the display panel, and at least part of the bendable portion is embedded into the third groove.

12. The display apparatus of claim 11, wherein the supporting portion comprises a fifth plane facing the display panel, and the fifth plane is between the bendable portion and the display panel.

13. The display apparatus of claim 11, wherein the at least one side of the bendable portion is provided with S first grooves, and each first groove is filled with a part of the material of the supporting portion, and wherein S is greater than or equal to 1, and
wherein each first groove is filled with the part of the material of the supporting portion by hot pressing the part of the material of the supporting portion into each first groove; or
wherein each first groove is filled with the part of the material of the supporting portion by embedding S third protrusions in the third groove one by one into the S first grooves.

14. (canceled)

15. The display apparatus of claim 1, wherein the first groove comprises a riveting hole, and
the supporting portion is connected to the bendable portion through the first groove by using a riveting process.

16. The display apparatus of claim 3, wherein a bottom of the first groove is provided with at least one riveting hole, and
the first protrusion is matched and connected with the first groove through a riveting process.

17. The display apparatus of claim 1, wherein the material of the supporting portion is plastic, the at least one side of the bendable portion comprises L fourth protrusions extending in a direction parallel to the display panel, the first groove is formed between any two adjacent fourth protrusions, and wherein L is greater than or equal to 2,
wherein at least part of the plastic is filled into each first groove through an injection molding process, and
wherein a length of a bottom of the first groove is greater than a length of a notch of the first groove.

18. (canceled)

19. The display apparatus of claim 1, wherein the material of the bendable portion comprises a metal material, and the material of the supporting portion comprises carbon fiber prepreg or plastic,
wherein the material of the supporting portion is carbon fiber prepreg, and the supporting portion is formed by laying K layers of carbon fiber prepreg, and wherein K is an odd number greater than 1, and
wherein an elastic modulus of one of any adjacent two layers of carbon fiber prepreg among the K layers of carbon fiber prepreg is different from an elastic modulus of the other one of the any adjacent two layers of carbon fiber prepreg among the K layers of carbon fiber prepreg.

20. (canceled)

21. (canceled)

22. (canceled)

23. The display apparatus of claim 1, wherein the density of the material of the bendable portion is greater than the density of the material of the supporting portion; and/or
wherein an elastic modulus of the material of the bendable portion is greater than an elastic modulus of the material of the supporting portion.

24. (canceled)

25. (canceled)

26. A method of manufacturing a supporting member, wherein the supporting member is provided in the display apparatus of claim 1, the display apparatus comprises a display panel, and the method comprises:
forming a bendable portion by using a first material, wherein the bendable portion comprises a first groove on at least one side of the bendable portion and is configured to support the bendable region of the display panel; and
forming a supporting portion by using a second material, wherein the supporting portion is connected to the bendable portion through the first groove and configured to support the non-bending region, and
wherein a density of a material of the bendable portion is different from a density of a material of the supporting portion,
wherein the supporting portion comprises an overlap,
the method further comprising:
connecting the supporting portion to the bendable portion through the first groove,
wherein the connecting the supporting portion to the bendable portion through the first groove comprises:
placing the supporting portion and the bendable portion in a hot pressing mold, wherein a depth of a region corresponding to the supporting portion in the hot pressing mold is different from a depth of a region corresponding to the bendable portion in the hot pressing mold; and
connecting the overlap of the supporting portion to the first groove of the bendable portion by using a hot pressing process.

27. (canceled)

28. An electronic device, comprising the display apparatus of claim 1.
